(19) United States
(12) Patent Application Publication
(10) Pub. No.: US 2022/0355419 A1
(43) Pub. Date: Nov. 10, 2022

(54) THINNED WAFER MANUFACTURING METHOD AND THINNED WAFER MANUFACTURING DEVICE

(71) Applicant: LINTEC CORPORATION, Tokyo (JP)

(72) Inventor: Naofumi IZUMI, Tokyo (JP)

(73) Assignee: LINTEC CORPORATION, Tokyo (JP)

(21) Appl. No.: 17/869,062

(22) Filed: Jul. 20, 2022

Related U.S. Application Data
(63) Continuation of application No. PCT/JP2021/009493, filed on Mar. 10, 2021.

(30) Foreign Application Priority Data
Mar. 24, 2020 (JP) 2020-053372

(51) Int. Cl. B23K 26/53; H01L 21/304; B23K 26/38; B23K 26/08

(52) U.S. Cl. CPC B23K 26/53; H01L 21/304; B23K 26/38; B23K 26/08

(57) ABSTRACT

A method of manufacturing a thinned wafer by separating a residual wafer from the thinned wafer, the method including: a weak layer forming step of forming a planar weak layer WL along one surface WFA of a semiconductor wafer WF to divide the semiconductor wafer WF into a thinned wafer WF1 and a residual wafer WF2 with the weak layer WL as a boundary; and a separating step of supporting at least one of a thinned wafer WF1 side and a residual wafer WF2 side of the semiconductor wafer WF and separating the thinned wafer WF1 and the residual wafer WF2 from each other, wherein the separation of the thinned wafer WF1 and the residual wafer WF2 gradually progresses from one end WFF in an outer edge of the semiconductor wafer WF toward the other end WFR in the outer edge of the semiconductor wafer WF.

### BACKGROUND OF THE INVENTION

### Field of the Invention

The present invention relates to a thinned wafer manufacturing method and a thinned wafer manufacturing device, and for example, relates to a method and a device to manufacture a semiconductor wafer whose thickness is reduced from the original thickness.

### Description of the Related Art

Examples of a thinned wafer manufacturing method include a method to form a thinned wafer from a semiconductor wafer (hereinafter, also referred to simply as a “wafer”) by forming a weak layer in the wafer. In one example of this method, at the time of dividing the original wafer into an upper half and a lower half, the total load required to separate the whole upper-half wafer (this is to be a residual wafer) from the lower-half wafer (this to be the thinned wafer) is applied to the thinned wafer and the residual wafer at a time in the initial period of their relative movement.

### SUMMARY OF THE INVENTION

The present invention disclosed and claimed herein, in one aspect thereof, comprises a thinned wafer manufacturing method. The method comprises:

a weak layer forming step of forming a planar weak layer along one surface of a semiconductor wafer to divide the semiconductor wafer into a thinned wafer and a residual wafer with the weak layer as a boundary; and

a separating step of supporting at least one of a thinned wafer side and a residual wafer side of the semiconductor wafer and separating the thinned wafer and the residual wafer from each other, wherein the separation of the thinned wafer and the residual wafer gradually progresses from one end in an outer edge of the semiconductor wafer toward the other end in the outer edge of the semiconductor wafer.

Further scope of applicability of the present invention will become apparent from the detailed description given hereinafter. The detailed description and embodiments are only given as examples though showing preferred embodiments of the present invention, and therefore, from the contents of the following detailed description, changes and modifications of various kinds within the spirits and scope of the invention will become apparent to those skilled in the art.

### BRIEF DESCRIPTION OF THE DRAWINGS

The present invention will be fully understood from the following detailed description and the accompanying drawings. The accompanying drawings only show examples and are not intended to restrict the present invention. In the accompanying drawings:

FIG. 1A to FIG. 1E are explanatory views of a thinned wafer manufacturing device according to a first embodiment;

FIG. 2A and FIG. 2B are explanatory views of the thinned wafer manufacturing device according to the first embodiment;

FIG. 3A is an explanatory view of a thinned wafer manufacturing device according to a second embodiment; and

FIG. 3B and FIG. 3C are explanatory views of modification examples.

### DETAILED DESCRIPTION

Embodiments will be hereinafter described based on the drawings.

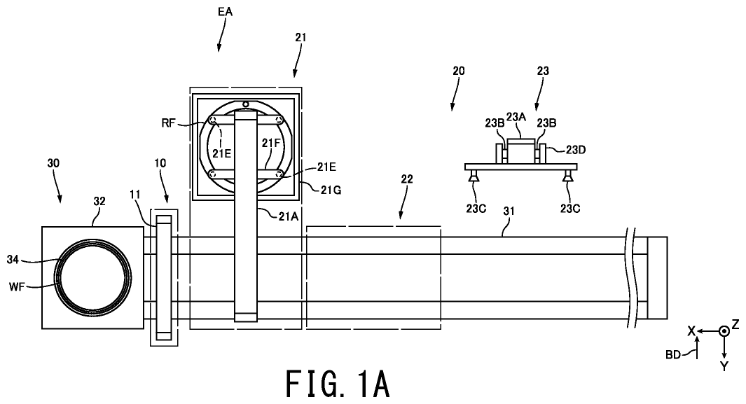

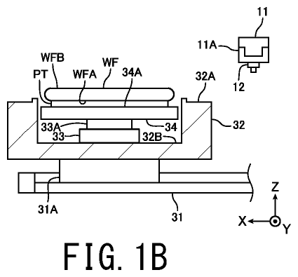

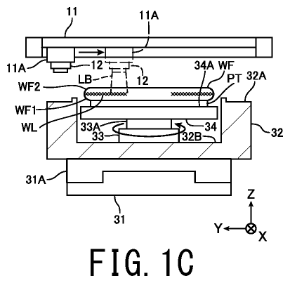

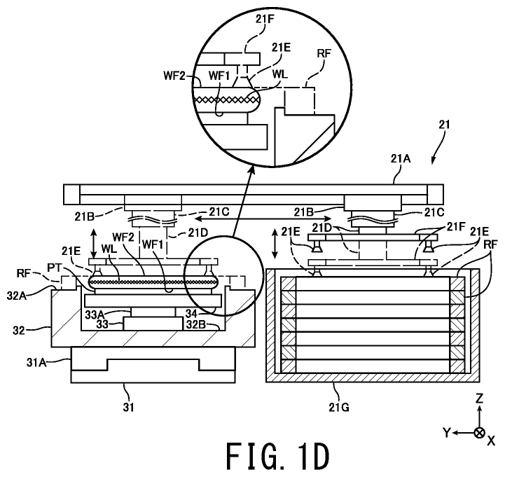

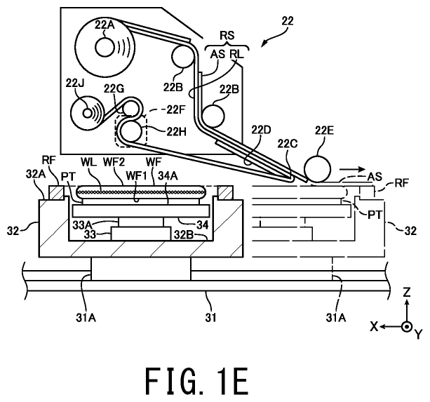

It should be noted that X-axis, Y-axis, and Z-axis in the embodiments are orthogonal to one another, where the X-axis and the Y-axis are within a predetermined plane while the Z-axis is orthogonal to the predetermined plane. Further, in the embodiments, FIG. 1A as viewed in the BD arrow direction parallel to the Y-axis is used as a reference for direction, and when a direction is mentioned without any designation of a drawing, an “upper” direction means a direction indicated by an arrow along the Z-axis, a “lower” direction means a direction opposite the upper direction, a “left” direction means a direction indicated by an arrow along the X-axis, a “right” direction means a direction opposite the “left” direction, a “front” direction means a direction toward the near side in FIG. 1A in terms of a direction parallel to the Y-axis, and a “rear” direction means a direction opposite the “front” direction.

### First Embodiment

A thinned wafer manufacturing device EA includes: a weak layer forming unit 10 which forms a planar weak layer WL along one surface WFA of a wafer WF to divide the wafer WF into a thinned wafer WF1 and a residual wafer WF2 with the weak layer WL as a boundary; and a separating unit 20 which supports a residual wafer WF2 side of the wafer WF and separates the thinned wafer WF1 and the residual wafer WF2 from each other. The thinned wafer manufacturing device EA is arranged near a wafer transfer unit 30 which supports and transfers the wafer WF.

The wafer WF has the surface WFA and the other surface WFB, and a not-illustrated predetermined circuit is formed on the surface WFA side, and a protect tape TP is pasted on a surface of the circuit.

The weak layer forming unit 10 includes a laser irradiation device 12 supported by a slider 11A of a linear motor 11 as a drive device and capable of radiating laser beams LB. The laser irradiation device 12 sets its focal points to predetermined positions of the inside of the wafer WF to form the weak layer WL at the focal positions. In this embodiment, an output part of the laser irradiation device 12 is formed such that the plurality of focal points line up in the left-right direction.

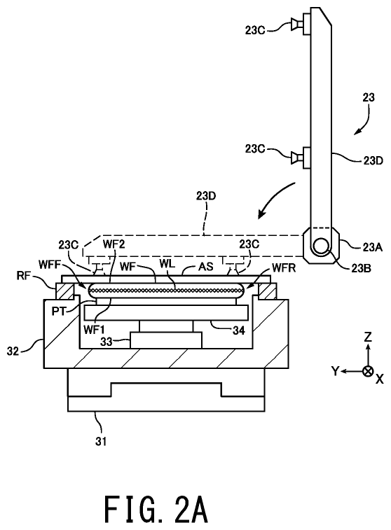

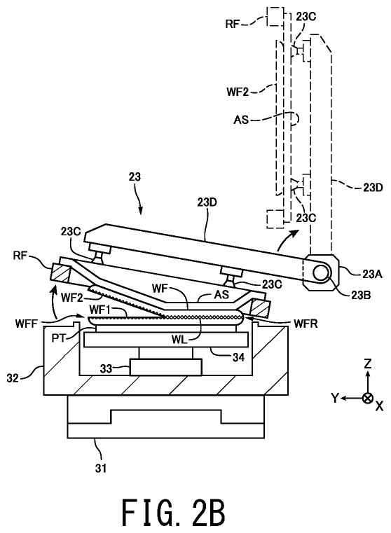

The separating unit 20 includes: a placing unit 21 which places a ring frame RF as a frame member around the wafer WF supported by the wafer transfer unit 30; a sheet pasting unit 22 which pastes an adhesive sheet AS on the wafer WF and the ring frame RF; and a separating force applying unit which separates the thinned wafer WF1 and the residual wafer WF2 from each other. The separation of the thinned wafer WF1 and the residual wafer WF2 by the separating unit 20 gradually progresses from one end WFF in an outer edge of the wafer WF toward the other end WFR in the outer edge of the wafer WF (see FIG. 2A and FIG. 2B).

The placing unit 21 includes: a direct-acting motor 21C as a drive device supported by a slider 21B of a linear motor 21A as a drive device; a suction arm 21F supported by an output shaft 21D of the direct-acting motor 21C and having suction parts 21E capable of suction-holding owing to a not-illustrated pressure-reducing unit (holding unit) such as a pressure-reducing pump or a vacuum ejector; and a stocker 21G in which the ring frames RF are stocked.

The sheet pasting unit 22 includes: a support roller 22A which supports a raw sheet RS in which the adhesive sheets AS are temporarily bonded to a band-shaped release liner RL; a guide roller 22B which guides the raw sheet RS; a releasing plate 22D as a releasing unit which folds the release liner RL at its releasing edge 22C to release the adhesive sheet AS from the release liner RL; a press roller 22E as a press unit which presses the adhesive sheet AS against the ring frame RF and the wafer WF to paste the adhesive sheet AS; a drive roller 22H which is supported by a not-illustrated output shaft of a rotary motor 22F as a drive device and sandwiches the release liner RL between itself and a pinch roller 22G; and a recovering roller 22J as a recovering unit which is supported by an output shaft of a not-illustrated drive device and constantly applies a predetermined tension to the release liner RL present between itself and the pinch roller 22G during the automatic operation of the thinned wafer manufacturing device EA, to recover the release liner RL.

The separating force applying unit 23 includes a suction arm 23D supported by an output shaft 23B of a rotary motor 23A as a drive device and having suction parts 23C capable of suction-holding owing to a not-illustrated pressure-reducing unit (holding unit) such as a pressure-reducing pump or a vacuum ejector.

The wafer transfer unit 30 includes: an outer table 32 supported by a slider 31A of a linear motor 31 as a drive device and having a frame mounting surface 32A capable of suction-holding owing to a not-illustrated pressure-reducing unit (holding unit) such as a pressure-reducing pump or a vacuum ejector; a rotary motor 33 as a drive device arranged in a dent 32B formed in the outer table 32; and an inner table 34 supported by an output shaft 33A of the rotary motor 33 and having a support surface 34A capable of suction-holding owing to a not-illustrated pressure-reducing unit such as a pressure-reducing pump or a vacuum ejector.

The operation of the above-described thinned wafer manufacturing device EA will be described.

First, a user of the thinned wafer manufacturing device EA (hereinafter, simply referred to as a “user”) sets the raw sheet RS as illustrated in FIG. 1E in the thinned wafer manufacturing device EA in which its members are arranged at the initial positions indicated by the solid lines in FIG. 1A to FIG. 1E (as for only the wafer transfer unit 30, its initial position is shown in FIG. 1A and FIG. 1B), and then inputs an automatic operation start signal through a not-illustrated operation unit such as an operation panel or a personal computer. In response, the separating unit 20 drives the rotary motor 22F to feed out the raw sheet RS, and when the feeding-direction leading end of the top adhesive sheet AS is released by a predetermined length at the releasing edge 22C of the releasing plate 22D, the separating unit 20 stops driving the rotary motor 22F. Next, when the user or a not-illustrated transfer unit such as a multi-joint robot or a belt conveyor places the wafer WF on the inner table 34 as illustrated in FIG. 1A and FIG. 1B, the wafer transfer unit 30 drives the not-illustrated pressure-reducing unit to start the suction-holding of the wafer WF on the support surface 34A. Thereafter, the wafer transfer unit 30 drives the linear motor 31 to move the slider 31A rightward, and when the left-right direction middle position of the wafer WF reaches the left-right direction middle position of the laser irradiation device 12 in a front view seen in the BD arrow direction, the wafer transfer unit 30 stops driving the linear motor 31.

Next, the weak layer forming unit 10 and the wafer transfer unit 30 drive the linear motor 11, the laser irradiation device 12, and the rotary motor 33 to move the laser irradiation device 12 from the outer edge side of the wafer WF toward its center while rotating the wafer WF as indicated by the two-dot chain line in FIG. 1C. Consequently, the planar weak layer WL along the surface WFA is formed inside the wafer WF where the focal positions of the laser irradiation device 12 are present. Then, when the weak layer WL is formed all over the focal positions of the laser irradiation device inside the wafer WF to divide the wafer WF into the thinned wafer WF1 and the residual wafer WF2, the weak layer forming unit 10 and the wafer transfer unit 30 stop driving the laser irradiation device 12 and the rotary motor 33, and thereafter the week layer forming unit 10 drives the linear motor 11 to return the laser irradiation device 12 to the initial position.

Next, the wafer transfer unit 30 drives the linear motor 31 to move the slider 31A rightward, and when the left-right direction middle position of the wafer WF reaches the left-right direction middle position of the suction arm 21F in the front view, the wafer transfer unit 30 stops driving the linear motor 31. Thereafter, the separating unit 20 drives the direct-acting motor 21C to bring the suction parts 21E into contact with the upper surface of the ring frame RF in the stocker 21G as indicated by the two-dot chain line in FIG. 1D, and thereafter drives the not-illustrated pressure-reducing unit to start the suction-holding of the ring frame RF on the suction parts 21E. Next, when the separating unit 20 drives the linear motor 21A and the direct-acting motor 21C to place the suction-held ring frame RF on the frame mounting surface 32A as indicated by the two-dot chain line in FIG. 1D, the wafer transfer unit 30 drives the not-illustrated pressure-reducing unit to start the suction-holding of the ring frame RF on the frame mounting surface 32A. Then, the separating unit 20 stops driving the not-illustrated pressure-reducing unit to cancel the suction-holding of the ring frame RF on the suction parts 21E and thereafter drives the linear motor 21A and the direct-acting motor 21C to return the suction arm 21F to the initial position.

Next, the wafer transfer unit 30 drives the linear motor 31 to move the slider 31A rightward, and when the slider 31A reaches a predetermined position, the separating unit 20 drives the rotary motor 22F to feed out the raw sheet RS in pace with the moving speed of the slider 31A. Consequently, the adhesive sheet AS is released from the release liner RL, and the adhesive sheet AS released from the release liner RS is pressed against the upper surface side of the ring frame RF and the residual wafer WF2 side of the wafer WF by the press roller 22E to be pasted as indicated by the two-dot chain line in FIG. 1E. Thereafter, the entire top adhesive sheet AS is pasted on the ring frame RF and the wafer WF, and when the feeding-direction leading end of an adhesive sheet AS next to the top adhesive sheet AS is released by a predetermined length at the releasing edge 22C of the releasing plate 22D, the separating unit 20 stops driving the rotary motor 22F.

Thereafter, the wafer transfer unit 30 continues to move the slider 31A rightward, and when the left-right direction middle position of the ring frame RF reaches the left-right direction middle position of the suction arm 23D in the front view, the wafer transfer unit 30 stops driving the linear motor 31. Next, the separating unit 20 drives the rotary motor 23A to bring the suction parts 23C into contact with the upper surface of the ring frame RF as indicated by the two-dot chain line in FIG. 2A, and thereafter drives the not-illustrated pressure-reducing unit to start the suction-holding of the ring frame RF on the suction parts 23C. Then, the wafer transfer unit 30 stops driving the not-illustrated pressure-reducing unit to cancel the suction-holding of the ring frame RF on the frame mounting surface 32A, and thereafter the separating unit 20 drives the rotary motor 23A to return the suction arm 23D to the initial position. At this time, the residual wafer WF2 is separated from the thinned wafer WF1, the separation gradually progressing from the one end WFF of the wafer WF toward its other end WFR as illustrated in FIG. 2B.

Next, when the whole residual wafer WF2 is separated from the thinned wafer WF1 and the suction arm 23D returns to the initial position, the wafer transfer unit 30 stops driving the not-illustrated pressure-reducing unit to cancel the suction-holding of the thinned wafer WF1 on the support surface 34A. Thereafter, when the user or the not-illustrated transfer unit supports the thinned wafer WF1 to transfer the thinned wafer WF1 to the next step, the wafer transfer unit 30 drives the linear motor 31 to return the slider 31A to the initial position. Thereafter, the same operation as above is repeated. Since the separating unit 20 stops driving the not-illustrated pressure-reducing unit to cancel the suction-holding of the ring frame RF on the suction parts 23C when the suction arm 23D returns to the initial position, the user or the not-illustrated transfer unit transfers the residual wafer WF2 supported by the ring frame RF through the adhesive sheet AS to a predetermined recovery position.

According to the above-described first embodiment, since the thinned wafer WF1 and the residual wafer WF2 are gradually separated, the total load required to separate the whole residual wafer WF2 from the thinned wafer WF1 is not applied to the thinned wafer WF1 and the residual wafer WF2 at a time in the initial period of their relative movement. This can prevent damage to the thinned wafer WF1 as much as possible when the residual wafer WF2 is separated from the thinned wafer WF1.

### Second Embodiment

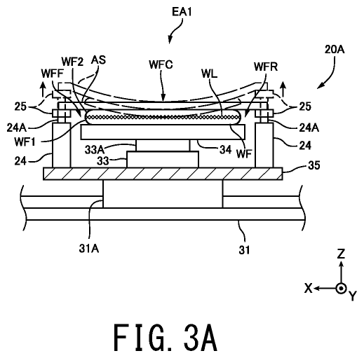

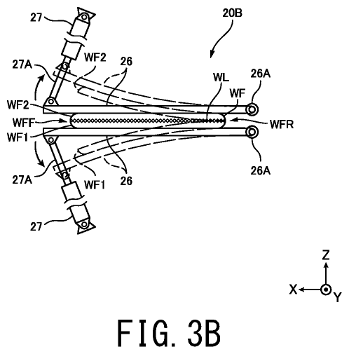

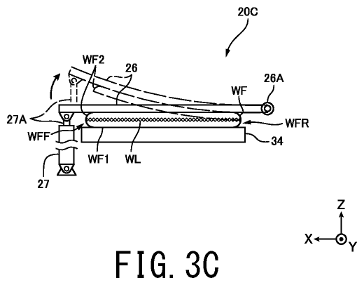

For example, the thinned wafer manufacturing device may be configured as a thinned wafer manufacturing device EA1 including a separating unit 20A illustrated in FIG. 3A in place of the separating unit 20 in the first embodiment. Note that, in the second embodiment, what have the same structures and the same functions as those of the first embodiment are denoted by the same reference signs as those of the first embodiment and their configuration description will be omitted, and their operation description and illustrations will be simplified.

Specifically, the separating unit 20A is supported by a lower table 35 instead of the outer table 32 of the wafer transfer unit 30 in the first embodiment, includes a pair of left and right direct-acting motors 24 and sheet receiving tables 25 respectively supported by output shafts 24A of these direct-acting motors 24, and separates the thinned wafer WF1 and the residual wafer WF2 from each other, the separation gradually progressing from the end WFF in the outer edge of the wafer WF toward the center WFC of the wafer WF. Note that the separating unit 20A included in the thinned wafer manufacturing device EA1 does not include the placing unit 21.

In the thinned wafer manufacturing device EA1 described above, after the weak layer forming unit 10 divides the wafer WF into the thinned wafer WF1 and the residual wafer WF2 as in the first embodiment, the separating unit 20A drives the rotary motor 22F to feed out the raw sheet RS in pace with the moving speed of the slider 31A. Consequently, as illustrated in FIG. 3A, the adhesive sheet AS is pressed against the upper surfaces of the sheet receiving tables 25 and the residual wafer WF2 side of the wafer WF to be pasted. Next, the separating unit 20A drives the direct-acting motors 24 to move up the sheet receiving tables 25 respectively supported by the direct-acting motors 24. Consequently, the residual wafer WF2 is separated from the thinned wafer WF1, the separation gradually progressing from the one end WFF and the other end WFR of the wafer WF toward the center WFC of the wafer WF as indicated by the two-dot chain line in FIG. 3A.

The second embodiment described above can also bring about the same effect as that of the first embodiment.

The invention is by no means limited to the above units and processes as long as the above operations, functions or processes of the units and processes are achievable, still less to the above merely exemplary structures and processes described in the exemplary embodiments. For instance, the weak layer forming unit may be any as long as it is capable of forming the planar weak layer along the one surface of the semiconductor wafer to divide the semiconductor wafer into the thinned wafer and the residual wafer with the weak layer as the boundary and is not limited as long as it is within the technical scope at the time of the filing of the application (the same applies to the other units and processes).

In the weak layer forming unit 10, the laser irradiation device 12 may be one whose focal points are dotted, linear, or planar. When the weak layer forming unit 10 forms the weak layer WL inside the wafer WF, the laser irradiation device 12 may be moved from the center of the rotating wafer WF toward its outer edge side, the laser irradiation device 12 may be moved relative to the stopping wafer WF, the wafer WF may be moved relative to the stopping laser irradiation device 12, or both may be moved. The weak layer forming unit 10 may form the weak layer WL at a time in the whole stopping or moving wafer WF or may form the weak layer WL in part of the stopping or moving wafer WF. The weak layer forming unit 10 may form the weak layer WL in the wafer WF in the state in which the left-right direction middle position of the wafer WF is not aligned with the left-right direction middle position of the laser irradiation device 12. The weak layer forming unit 10 may employ, instead of the laser, one that applies, for example, electromagnetic wave, vibration, heat, chemicals, chemical substance, or the like to change the properties, characteristics, nature, material, composition, configuration, size, or the like, thereby forming the weak layer WL in the wafer WF. The weak layer WL may be one that is parallel to the surface WFA, may be one that is inclined relative to the surface WFA, or may be one extending in the up-down direction or inclined relative to the up-down direction and having, for example, a lattice shape or other shape in a plan view so as to be capable of dividing the surface WFA into two or three sections or more. The weak layer WL may be one that makes the thinned wafer WF1 and the residual wafer WF2 completely apart from each other, or may be one that makes the thinned wafer WF1 and the residual wafer WF2 partially apart from each other. With the surface on which the circuit is not formed in the above embodiments being set as the one surface, the planar weak layer WL along this one surface may be formed. For example, two or more planar weak layers WL along the surface WFA of the wafer WF may be formed to divide the wafer WF into three or more, in which case the separating unit 20 separates the wafer WF into three or more.

The placing unit 21 may employ, as the frame member, an annular or non-annular member, for instance, instead of the ring frame RF. It is not essential that the thinned wafer manufacturing device of the present invention includes the placing unit 21.

The raw sheet fed out by the sheet pasting unit 22 may be one in which cuts in a closed-loop shape or all along the short width direction are formed in a band-shaped adhesive sheet base temporarily bonded to the release liner RL and predetermined regions demarcated by the cuts are the adhesive sheets AS, or the sheet pasting unit 22 may employ a raw sheet in which a band-shaped adhesive sheet base is temporarily bonded to the release liner RL, and form cuts in a closed-loop shape or all along the short width direction by a cutting unit to set predetermined regions demarcated by the cuts as the adhesive sheets AS. The sheet pasting unit 22 may paste the band-shaped adhesive sheet base on the wafer WF and the ring frame RF. When releasing the adhesive sheet AS from the release liner RL, the sheet pasting unit 22 may perform the torque control of the rotary motor 22F so that a predetermined tension is applied to the raw sheet RS. The raw sheet RS or the release liner RL may be supported or guided by a plate-shaped member, a shaft member, or the like instead of the rollers such as the support roller 22A and the guide roller 22B. The raw sheet RS may be supported in, for example, a fan-folded state instead of in a rolled-up state, to be drawn out. The sheet pasting unit 22 may employ a press unit that is supported by an output shaft of a direct-acting motor as a drive device, holds the adhesive sheet AS by its holding member capable of suction-holding owing to a not-illustrated pressure-reducing unit such as a pressure-reducing pump or a vacuum ejector, and presses the adhesive sheet AS held by the holding member against the wafer WF and the ring frame RF to paste the adhesive sheet AS. The release liner RL may be recovered in, for example, a fan-folded state or in a state of being cut into small pieces by a shredder or the like instead of in the rolled-up state, or the release liner RL may be recovered simply in a piled-up state instead of in the rolled-up state or the fan-folded state. The recovery of the release liner RL may be omitted. When pasting the adhesive sheet AS on the wafer WF and the ring frame RF, the sheet pasting unit 22 itself may move while the wafer WF and the ring frame RF move or do not move. The sheet pasting unit 22 may feed out an adhesive sheet AS to which the release liner RL is not temporarily bonded, to paste the adhesive sheet AS on the wafer WF and the ring frame RF. At the time of the pasting of the adhesive sheet AS on the wafer WF and the ring frame RF, the adhesive sheet AS may be turned upside down and may be set in landscape orientation.

The separating unit 20 may be configured to support the thinned wafer WF1 side of the wafer WF and separate the thinned wafer WF1 and the residual wafer WF2 from each other or may be configured to support both the thinned wafer WF1 side and the residual wafer WF2 side of the wafer WF and separate the thinned wafer WF1 and the residual wafer WF2 from each other.

As an embodiment of the separating unit, separating units 20B, 20C illustrated in FIG. 3B and FIG. 3C may be employed, for instance. The separating units 20B, 20C include: at least one elastically deformable support plate 26 which has one end supported by a rotary shaft bearing 26A and supports at least one of the thinned wafer WF1 side and the residual wafer WF2 side of the wafer WF by suction or gripping; and a direct-acting motor 27 as a drive device which has an output shaft 27A supporting the other end of the support plate 26 and separates the thinned wafer WF1 and the residual wafer WF2 through the support plate 26. As indicated by the two-dot chain line in FIG. 3B and FIG. 3C, the separating units 20B, 20C drive the direct-acting motor 27 and causes the curved deformation of the support plate 26 to separate the thinned wafer WF1 and the residual wafer WF2 from each other, whereby the separation of the thinned wafer WF1 and the residual wafer WF2 gradually progresses from the end WFF in the outer edge of the wafer WF toward the other end WFR in the outer edge of the wafer WF. Note that in the second embodiment, the direct-acting motors 24 included in the separating unit 20A need not be supported by the lower table 35.

It is not essential that the wafer transfer unit 30 is capable of suction-holding on the frame mounting surface 32A, and for example, it may support the rotary motor 33 through what is called an XY table and be combined with an imaging unit such as a camera or a projector or with a detecting unit such as any of various sensors such as an optical sensor or an ultrasonic sensor to form a positioning unit that positions the wafer WF or the thinned wafer WF1. Such a positioning unit may position the wafer WF, the thinned wafer WF1, or the like on a pre-stage of at least one of the weak layer forming unit 10 and the separating unit 20. In the case where it supports the rotary motor 33 through the XY table, the wafer transfer unit 30 may move the inner table 34 in at least one of the X-axis direction and the Y-axis direction when the weak layer WL is formed.

The wafer WF may have a circuit formed on at least one of the surface WFA and the other surface WFB, or may have no circuit formed on the surface WFA or the other surface WFB. The wafer WF may have a protect tape PT pasted on at least one of the surface WFA and the other surface WFB or may have no protect tape pasted on the surface WFA or the other surface WFB. The wafer WF may have a hard member such as glass or an iron plate pasted on at least one of the surface WFA and the other surface WFB through an adhesive unit such as a double-faced adhesive sheet or an adhesive.

The thinned wafer manufacturing devices EA, EA1 each may include a releasing unit that releases the protect tape PT or the hard member pasted on at least one of the surface WFA and the other surface WFB.

The thinned wafer manufacturing devices EA, EA1 each may include a polishing unit for chemical mechanical polishing, dry polishing, wet etching, dry etching, or the like that polishes the weak layer WL-side surface of at least one of the thinned wafer WF1 and the residual wafer WF2, and for example, may additionally include any processing unit such as a grinding unit that grinds or splits at least one of the thinned wafer WF1 and the residual wafer WF2, a coating unit that coats at least one of the thinned wafer WF1 and the residual wafer WF2 with paint such as a protect material or a covering material, an applying unit that applies an additive such as an adhesive or a processed substance on at least one of the thinned wafer WF1 and the residual wafer WF2, a plating unit that forms a metallic or nonmetallic coating film on at least one of the thinned wafer WF1 and the residual wafer WF2, a laminating unit that laminates at least one of the thinned wafer WF1 and the residual wafer WF2 with a laminate such as an adhesive sheet or a terminal (electrode), a cutting unit that forms cuts in at least one of the thinned wafer WF1 and the residual wafer WF2 to cut it, a singulation unit that singulates the thinned wafer WF1 by forming a weak layer having a lattice shape or other shape in a plan view in at least one of the thinned wafer WF1 and the residual wafer WF2 and applying tension to the thinned wafer WF1, and an expanding device that expands gaps between pieces formed by the singulation.

The materials, types, shapes, and so on of the adhesive sheet AS, the wafer WF, the thinned wafer WF1, and the residual wafer WF2 in the present invention are not limited. For example, the adhesive sheet AS, the wafer WF, the thinned wafer WF1, and the residual wafer WF2 may be in a circular shape, an elliptical shape, a polygonal shape such as a triangular shape or a quadrangular shape, or any other shape. The adhesive sheet AS may be of a pressure-sensitive bonding type, a heat-sensitive bonding type, or the like. If the adhesive sheet AS is of the heat-sensitive bonding type, it may be bonded by an appropriate method, for example, by an appropriate heating unit for heating the adhesive sheet AS, such as a coil heater or a heating side of a heat pipe. Further, such an adhesive sheet AS may be, for example, a single-layer adhesive sheet having only an adhesive layer, an adhesive sheet having an intermediate layer between an adhesive sheet base and an adhesive layer, a three or more-layer adhesive sheet having a cover layer on the upper surface of an adhesive sheet base, or an adhesive sheet such as what is called a double-faced adhesive sheet in which an adhesive sheet base is releasable from an adhesive layer. The double-faced adhesive sheet may be one having one intermediate layer or more, or may be a single-layer one or a multilayer one not having an intermediate layer. Further, the wafer WF, the thinned wafer WF1, and the residual wafer WF2 each may be, for example, a silicon semiconductor wafer or a compound semiconductor wafer. Note that the adhesive sheet AS may be read as one indicating its function or application, and may be, for example, any sheet, film, tape, or the like such as an information entry label, a decoration label, a protect sheet, a dicing tape, a die attach film, a die bonding tape, or a recording layer forming resin sheet.

The drive devices in the above-described embodiments each may be an electric machine such as a rotary motor, a direct-acting motor, a linear motor, a uniaxial robot, or a multi-joint robot having biaxial or triaxial or more joints, or may be an actuator such as an air cylinder, a hydraulic cylinder, a rodless cylinder, or a rotary cylinder, or the like. One in which some of these are directly or indirectly combined can also be employed.

In the above-described embodiments, in the case where a rotating member such as a roller is employed, a drive device that drives the rotation of the rotating member may be provided, and the surface of the rotating member or the rotating member itself may be formed of a deformable member such as rubber or resin or the surface of the rotating member or the rotating member itself may be formed of a non-deformable member. A member that rotates or does not rotate, such as a shaft or a blade, may be employed instead of the roller. In the case where one that presses an object to be pressed, such as a press unit or a press member such as a press roller or a press head, is employed, a member such as a roller, a round bar, a blade member, rubber, resin, or sponge may be employed or a structure that sprays gaseous substance such as the atmospheric air or gas for pressing may be employed, instead of or in addition to those exemplified in the above, and the one that presses may be formed of a deformable member such as rubber or resin or may be formed of a non-deformable member. In the case where one that releases an object to be released, such as a releasing unit or a releasing member such as a releasing plate or a releasing roller is employed, a member such as a plate-shaped member, a round bar, or a roller may be employed instead of or in addition to those exemplified above, and the one that releases may be formed of a deformable member such as rubber or resin or may be formed of a non-deformable member. In the case where one that supports (holds) a member to be supported (member to be held), such as a support (holding) unit or a support (holding) member, is employed, the member to be supported may be supported (held) by a gripping unit such as a mechanical chuck or a chuck cylinder, Coulomb force, an adhesive (adhesive sheet, adhesive tape), a tackiness agent (tacky sheet, tacky tape), magnetic force, Bernoulli suction, suction attraction, a drive device, or the like. In the case where one that cuts a member to be cut or that forms a cut or a cutting line in a member to be cut, such as a cutting unit or a cutting member, is employed, one that cuts using a cutter blade, a laser cutter, ion beams, thermal power, heat, water pressure, a heating wire, or the spraying of gas, liquid, or the like may be employed instead of or in addition to those exemplified above, and at the time of the cutting, an appropriate combination of drive devices may move the one that cuts the object to be cut.

What is claimed is:

1. A thinned wafer manufacturing method comprising:
a weak layer forming step of forming a planar weak layer along one surface of a semiconductor wafer to divide the semiconductor wafer into a thinned wafer and a residual wafer with the weak layer as a boundary; and
a separating step of supporting at least one of a thinned wafer side and a residual wafer side of the semiconductor wafer and separating the thinned wafer and the residual wafer from each other, wherein the separation of the thinned wafer and the residual wafer gradually progresses from one end in an outer edge of the semiconductor wafer toward the other end in the outer edge of the semiconductor wafer.

2. A thinned wafer manufacturing method comprising:
a weak layer forming step of forming a planar weak layer along one surface of a semiconductor wafer to divide the semiconductor wafer into a thinned wafer and a residual wafer with the weak layer as a boundary; and
a separating step of supporting at least one of a thinned wafer side and a residual wafer side of the semiconductor wafer and separating the thinned wafer and the residual wafer from each other, wherein the separation of the thinned wafer and the residual wafer gradually progresses from one end in an outer edge of the semiconductor wafer and the other end in the outer edge of the semiconductor wafer toward a center of the semiconductor wafer.

3. A thinned wafer manufacturing device comprising:
a weak layer forming unit which forms a planar weak layer along one surface of a semiconductor wafer to divide the semiconductor wafer into a thinned wafer and a residual wafer with the weak layer as a boundary; and
a separating unit which supports at least one of a thinned wafer side and a residual wafer side of the semiconductor wafer and separates the thinned wafer and the residual wafer from each other, wherein the separation of the thinned wafer and the residual wafer gradually progresses from one end in an outer edge of the semiconductor wafer toward the other end in the outer edge of the semiconductor wafer.

4. A thinned wafer manufacturing device comprising:
a weak layer forming unit which forms a planar weak layer along one surface of a semiconductor wafer to divide the semiconductor wafer into a thinned wafer and a residual wafer with the weak layer as a boundary; and
a separating unit which supports at least one of a thinned wafer side and a residual wafer side of the semiconductor wafer and separates the thinned wafer and the residual wafer from each other, wherein the separation of the thinned wafer and the residual wafer gradually progresses from one end in an outer edge of the semiconductor wafer and the other end in the outer edge of the semiconductor wafer toward a center of the semiconductor wafer.
